(19) United States
(12) Patent Application Publication
(10) Pub. No.: US 2008/0251949 A1
(43) Pub. Date: Oct. 16, 2008

(54) Molding apparatus, molded semiconductor package using multi-layered film, fabricating and molding method for fabricating the same

(75) Inventors: Wha-Su Sin, Cheonan-si (KR); Heui-Seog Kim, Cheonan-si (KR); Jong-Keun Jeon, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/078,801

(22) Filed: Apr. 4, 2008

(30) Foreign Application Priority Data
Apr. 12, 2007 (KR) 10-2007-0036149

(51) Int. Cl. H01L 21/56; H01L 21/67; H01L 23/28

(52) U.S. Cl. 257/787; 29/25.01; 438/127; 257/E21.001; 257/E23.116; 257/E21.502

(57) ABSTRACT

Example embodiments include molding apparatuses, semiconductor packages, a fabricating methods for fabricating the same. The molding apparatus may include a first mold die for adhering a partially completed package, a second mold die including a cavity formed such that the partially completed package is positioned inside the cavity and a molding resin for encapsulating the partially completed package inserted into the cavity, and a multi-layered film supply unit for supplying a multi-layered film to the cavity of the second mold die. The semiconductor package may include a substrate, a semiconductor chip electrically connected to the substrate, a molding resin for encapsulating the semiconductor chip and an electrical portion of the substrate, and a marking film, adhered to an outer surface of the molding resin such that a mark is marked in the marking film.

### PRIORITY STATEMENT

This application claims priority under 35 U.S.C. §119 to Korean Patent Application No. 2007-0036149, filed Apr. 12, 2007, the entire contents of which are incorporated herein by reference.

### BACKGROUND

1. Field

Example embodiments relate to a semiconductor package, a fabricating method thereof, and a molding apparatus and a molding method for fabricating the same.

2. Description of the Related Art

Manufacturing semiconductors may include various processes, including a fabrication (FAB) process for forming a plurality of semiconductor chips on a silicon wafer, an electrical die sorting (EDS) process for electrically inspecting and sorting a plurality of semiconductor chips formed on the wafer into non-defective chips and defective chips, an assembling process for individually separating and packaging the non-defective semiconductor chips, and a testing process for testing the packages.

In the assembling process, a semiconductor package may function-to-protect a semiconductor chip from an external environment and may connect the semiconductor chip physically and electrically to an electronic system. A conventional semiconductor package may have a structure in which a semiconductor chip may adhere to a substrate, e.g. a lead frame or printed circuit board (PCB), the semiconductor chip may be electrically connected to the substrate, and the semiconductor chip and an electrical connection portion of the substrate and the semiconductor chip may then be encapsulated in molding resin.

As semiconductor devices get lighter, slimmer, and more compact, the thickness of semiconductor packages is also gradually getting thinner, which may influence the semiconductor device's performance, price and reliability.

FIG. 1 is a cross-sectional view of a conventional semiconductor package, and FIG. 2 is a plan view of the semiconductor package of FIG. 1, viewed in direction A. Referring to FIGS. 1 and 2, a conventional semiconductor package 10 may include a substrate 11, a connection terminal 12, formed on the top surface of the substrate 11, solder ball lands 13, formed on the bottom surface of the substrate 11, a semiconductor chip 14, adhered to the top surface of the substrate 11, wires 19 for electrically connecting pads 15, which may be input/output terminals for the semiconductor chip 14, to the connection terminal 12 of the substrate 11; solder balls 18, adhered to the respective solder ball lands 13; and a molding resin 16 used to encapsulate an electrical connection portion of the substrate and the semiconductor chip. In addition, a mark 17 may be marked in the molding resin 16 indicating, for example, a lot number or management number.

FIG. 3 is a flowchart illustrating a conventional fabrication method of a semiconductor package. Referring to FIG. 3, a method of semiconductor packaging may include forming a ball grid array (BGA) package. This packaging method may include preparing a partially completed package (S22), molding the prepared partially completed package with a molding resin 16 (S23), adhering solder balls 18 to solder ball lands 13 on the molded partially completed package (S25), and irradiating a laser beam onto the molding resin 16, to mark the molding resin 16 (S26) with mark 17.

The partially completed package may include a package in which a semiconductor chip 14 may adhere to one surface of a substrate 11, and pads 15, that may serve as input/output terminals for the semiconductor chip 14, may be electrically connected to a connection terminal 12 of the substrate 11 through wires 19, but an electrical connection portion of the substrate 11 and the semiconductor chip 14 may not be molded with the molding resin 16. To obtain a finished semiconductor package 10, the partially completed package may then be molded and marked as shown in FIG. 3.

As semiconductor devices get lighter, slimmer, and more compact, the entire thickness (H of FIG. 1) of the semiconductor package 10 may gradually be reduced. To reduce the entire thickness H of the semiconductor package 10, the thickness of the molding resin 16 formed in the molding process, e.g., a gap (G of FIG. 1) between the top surfaces of the molding resin 16 formed in the molding process and the semiconductor chip 14, may be gradually reduced.

According to the conventional method of manufacturing a semiconductor package described above, the mark 17 (e.g., a lot number or management number) may be marked in the molding resin 16 formed during the molding process. However, the wire 19 may be damaged when marking the mark 17, if the gap G between the top surfaces of the molding resin 16 formed during the molding process and the semiconductor chip 14 has been gradually reduced to achieve a slimmer package. For example, if the thickness of the molding resin 16 formed during the molding process is relatively thin, and the gap G between the top surfaces of the molding resin 16 formed during the molding process anti the semiconductor chip 14 has been gradually reduced, a top portion (e.g., portion B of FIG. 1) of the wire 19 for electrically connecting the semiconductor chip 14 to the substrate 11 may be positioned too close to the top surface of the molding resin 16. Therefore, when irradiating a laser beam onto the top surface of the molding resin 16 to make mark 17, the wire 19 in the molding resin 16 may be partially damaged or cut by the irradiation of the laser beam, and the partially-damaged or cut wire 19 may be exposed to the outside of the molding resin 16 through mark 17.

### SUMMARY

Example embodiments are directed to molding apparatuses, semiconductor packages capable of preventing a wire from being damaged when marking a mark, fabrication methods of the semiconductor packages, and molding methods for fabricating the semiconductor packages. Example embodiments provide a semiconductor package capable of protecting and preventing a wire from being exposed to the outside of a molding resin during marking due to a failure of a portion of the molding resin generated in a molding process.

According to example embodiments, an apparatus for molding a semiconductor package may include a first mold die and a second mold die. The first mold die may be used to adhere a partially completed package onto the first mold die. The second mold die may have a cavity formed therein such that a partially completed package may be positioned inside the cavity. The second mold die may also have molding resin inserted into the cavity, which may be used to encapsulate a partially completed package. The apparatus may also include a multi-layered film supply unit that may supply or provide a multi-layered film to the second mold die cavity.

The multi-layered film may include a release film and a marking film. The marking film may have a thermosetting point lower than that of the release film and may be include a color tape. The multi-layered film may further include a foaming film between the release film and the marking film, which may produce gas during curing of the molding resin such that the release and marking films separate from each other.

According to other example embodiments, a semiconductor package may be formed using the molding apparatus and include a substrate and a semiconductor chip electrically connected to the substrate. A molding resin may be used to encapsulate the semiconductor chip and an electrical portion of the substrate and a marking film may be on an outer surface of the molding resin having a mark.

The marking film may include a color tape and may adhere to the outer surface of the molding resin by pressure and/or heat. The semiconductor package may further include a wire for electrically connecting an input/output terminal of the substrate to an input/output terminal of the semiconductor chip. The molding resin may further encapsulate the semiconductor chip, the wire, and an electrical connection portion of the substrate.

According to other example embodiments, a method for fabricating a semiconductor package using the molding apparatus may include molding a partially completed package with molding resin, adhering a marking film to the molding resin and marking the marking film with a mark. The partially completed package may include a substrate and a semiconductor chip electrically connected to the substrate. Adhering the marking film to the molding resin may occur during molding of the partially completed package and may further include pressing and adhering the marking film to the molding resin using heat and/or pressure when molding the partially completed package. The marking film may include a color tape and the mark in the marking film may be made by irradiating a laser beam onto the marking film.

Molding the partially completed package with a molding resin may further include adhering the partially completed package to a first mold die and positioning the partially completed package inside a cavity of a second mold die. A molding resin may be inserted into the cavity and the molding resin may flow into the cavity and be cured using the first and second mold dies. The molded partially completed package may also be withdrawn from the cavity. The curing may include the use of heat and/or pressure.

The method for fabricating a semiconductor package may further include, using a multi-layered film supply unit, which may provide a multi-layered film to the cavity of the second mold die. The multi-layered film may include a release film and a marking film, and the release film may contact the cavity of the second mold die, while the marking film may contact the molding resin. The multi-layered film may also be inserted into the cavity before inserting the molding resin. The method may also include separating the release film and the marking film when withdrawing the molded partially completed package from the cavity. The marking film may have a thermosetting point lower than that of the release film and may include color tape. The multi-layered film may further include a foaming film between the release film and the marking film, which may produce gas during curing of the molding resin such that the marking and release films separate from each other.

According to other example embodiments, a method for molding a semiconductor package using the molding apparatus may include adhering the partially completed package to a first mold die and positioning the partially completed package inside a cavity of a second mold die. The method may also include using a multi-layered film supply unit to supply or provide a multi-layered film to the cavity of the second mold die. The method may also include inserting a molding resin into the cavity, the molding resin may be used to encapsulate the partially completed package.

The method may further include, curing the molding resin by pressurizing and/or heating the molding resin using the first and second. The method may also include separating the multi-layered film and withdrawing the molded partially completed package from the cavity.

The multi-layered film may include a release film that contacts the cavity of the second mold die and a release film that contacts the molding resin. The release film may be used to separate the molding resin from the second mold die when withdrawing the molded partially completed package from the cavity. The marking film may be pressed and fixed to the molding resin when curing the molding resin. The curing may include pressurizing and/or heating. The marking film may be formed of a material having a thermosetting point lower than that of the release film and may also include a color tape.

The multi-layered film may further include a foaming film between the release film and the marking film, which may produce gas during curing of the molding resin such that the release and marking films separate from each other.

### BRIEF DESCRIPTION OF THE DRAWINGS

The above and other features and advantages of example embodiments will become more apparent by describing in detail example embodiments with reference to the attached drawings. The accompanying drawings are not to be considered as drawn to scale unless explicitly noted.

FIG. 1 is a cross-sectional view of a conventional semiconductor package;

FIG. 2 is a plan view of the semiconductor package of FIG. 1, viewed in direction A;

FIG. 3 is a flowchart illustrating a conventional fabrication method of a semiconductor package;

FIG. 4 is a cross-sectional view of a semiconductor package molding apparatus according to example embodiments;

FIG. 5 is a cross-sectional view illustrating one die of the molding apparatus of FIG. 4 having moved by a predetermined or given distance;

FIG. 6 is a cross-sectional view of a semiconductor package molding apparatus according to example embodiments;

FIG. 7 is an enlarged cross-sectional view of portion C of FIG. 6;

FIG. 8 is a flowchart illustrating a semiconductor package molding method according to example embodiments;

FIG. 9 is a cross-sectional view of a partially completed package molded by a semiconductor package molding apparatus according to example embodiments;

FIG. 10 is a cross-sectional view illustrating the state that solder balls are adhered to the partially completed package of FIG. 9 and then marked using a laser;

FIG. 11 is cross-sectional of a semiconductor package according to example embodiments; and

FIG. 12 is a flowchart illustrating a fabrication method of a semiconductor package according to example embodiments.

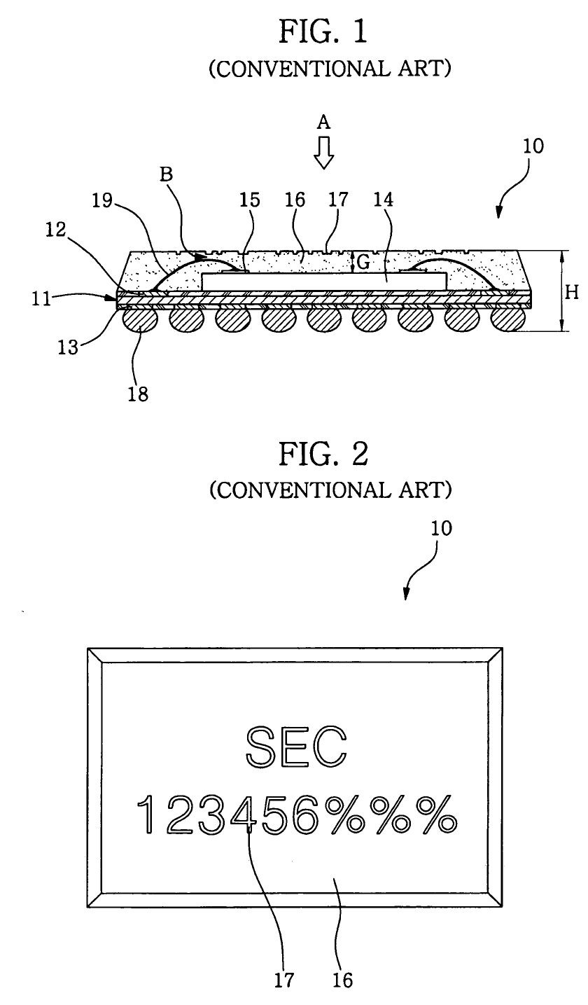

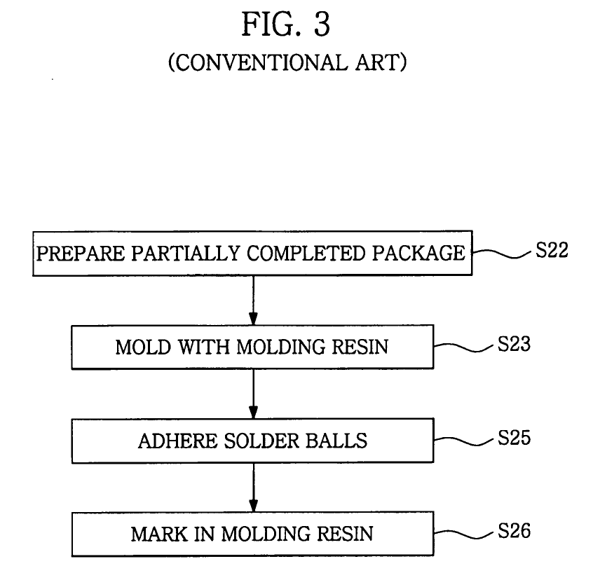

### DETAILED DESCRIPTION OF EXAMPLE EMBODIMENTS

Various example embodiments will now be described more fully with reference to the accompanying drawings in which some example embodiments are illustrated. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, e.g. “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g. those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, example embodiments are not limited to those described.

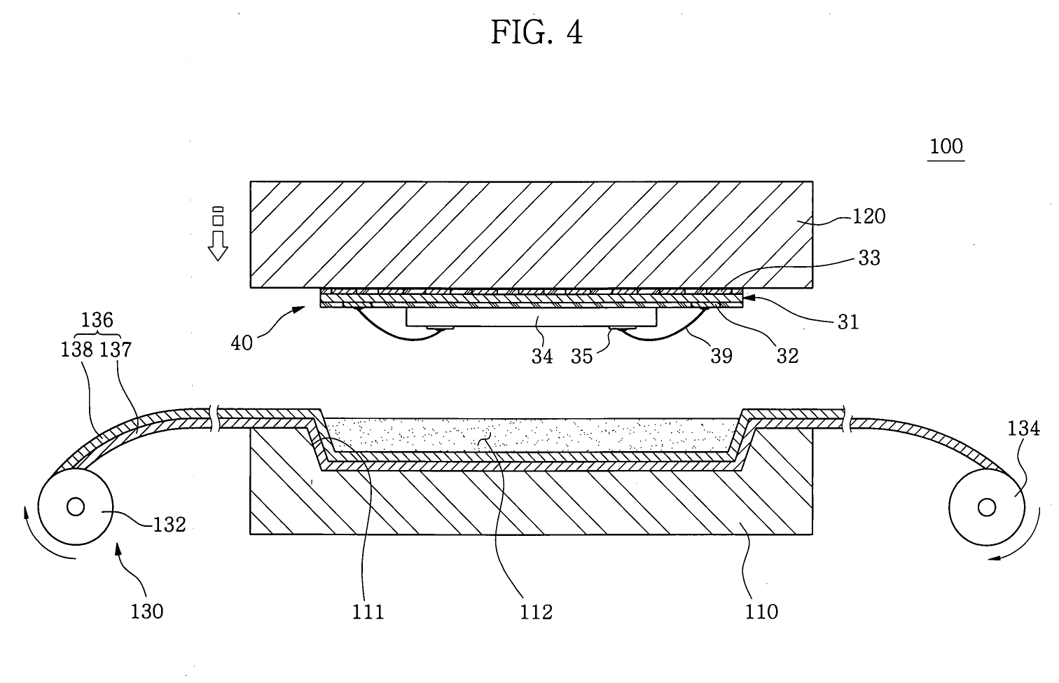

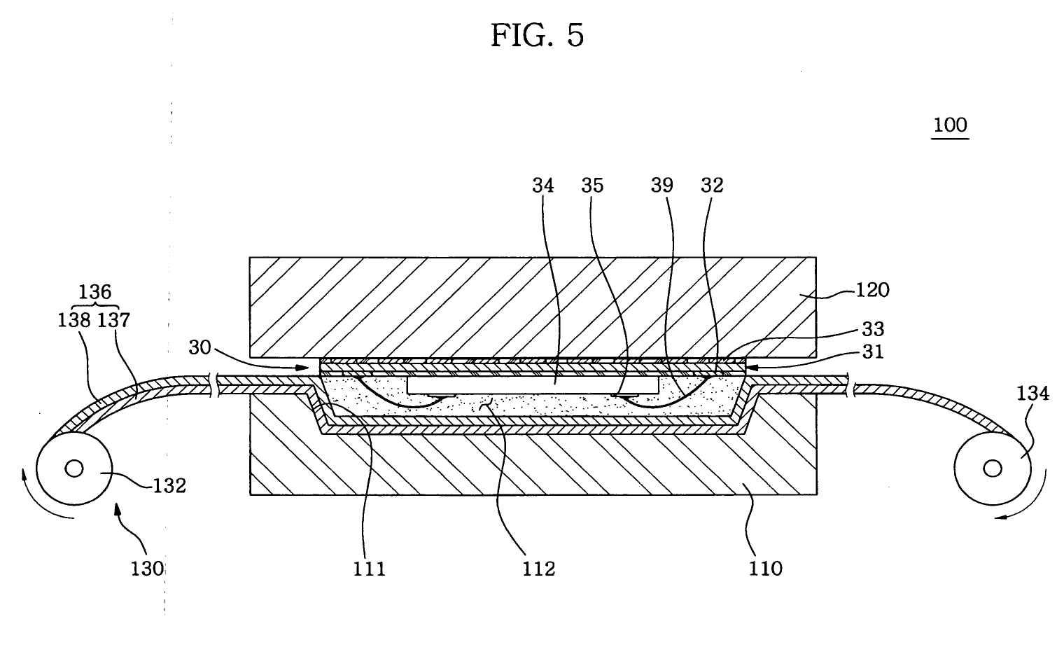

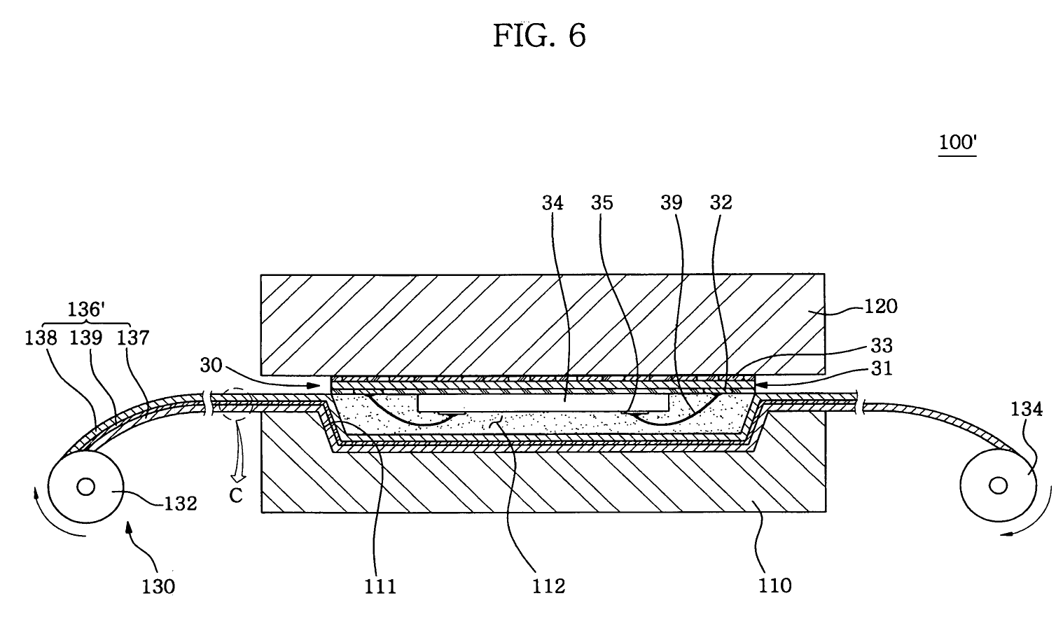

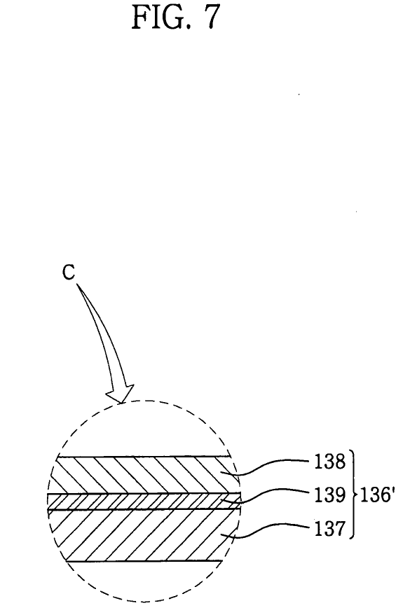

Example embodiments will now be described more fully with reference to the accompanying drawings. Example embodiments may, however, be embodied in many different forms and should not be construed as being limited to the embodiments set forth herein. Rather, these embodiments are provided so that this disclosure will be thorough and complete, and will fully convey the scope of example embodiments to one of ordinary skill in the art. In the drawings, the sizes of constitutional elements may be exaggerated for convenience of illustration. FIG. 4 shows a cross-sectional view of a semiconductor package molding apparatus according to an example embodiment, and FIG. 5 shows a cross-sectional view illustrating the state that one die of the molding apparatus of FIG. 4 is moved by a predetermined distance. FIG. 6 shows a cross-sectional view of a semiconductor package molding apparatus according to another example embodiment, and FIG. 7 shows an enlarged cross-sectional view of portion C of FIG. 6.

FIGS. 4 and 5, which may include a semiconductor package molding apparatus 100. The semiconductor package molding apparatus 100 may include a first mold die 120 and a second mold die 110. The first mold die 120 may have a partially completed package 40 attached thereto. The second mold die 110 may include a cavity 111. The cavity 111 may allow the partially completed package 40 to be positioned in the cavity 11. The cavity 111 may also have molding resin 12 inserted in to it and then heated so that the molding resin 12 flows and may be used to encapsulate the partially completed package 40 to form a molded partially completed package 30. The molding apparatus 100 may also include a multi-layered film supply unit 130 that may supply a multi-layered film 136 to the cavity 111. The multi-layered film 136 may be supplied or provided to the cavity 11 before the molding resin 12 flows into the cavity 111. As shown in FIG. 4, the first mold die 120 may be positioned on an upper portion of the molding apparatus, and the second mold die 110 may be positioned below the first mold die 120 to correspond to the position of the first mold die 120. The first mold die 120 may adhere the partially completed package 40 thereto using a suction force, e.g., vacuum.

The partially completed package 40 may include a semiconductor chip 34 adhered to one surface of a substrate 31, e.g., a lead frame or PCB. Partially completed package 40 may also include pads 35 that may act as input/output terminals for the semiconductor chip 34 to electrically connect the semiconductor chip 34 to a connection terminal 32 of the substrate 31 through wires 39. As shown in FIG. 4, the partially completed package 40 adhered to the first mold die 120, may not be molded, in other words, the semiconductor chip 34 and an electrical connection portion of the substrate 31 may not be molded with the molding resin 112.

As shown in FIG. 5, the first mold die 120 may be dropped or moved by a predetermined or given distance up or down, such that the partially completed package 40 adhered thereto using a suction force, e.g., vacuum, is positioned inside the cavity 111 of the second mold die 110. For example, the first mold die 120 may be mounted to move up and down at a predetermined or given distance. Alternatively, the second mold die 110 may move up and down a predetermined distance to the first mold die 120.

The multi-layered film supply unit 130 may include a film supply part 132, which may be formed in the shape of a reel, may rotate to supply the multi-layered film 136 and a film collecting part 134, which may also be formed in the shape of a reel may rotate and collect the entire or a portion of the multi-layered film 136. The film supply part 132 may be positioned on one side of the second mold die 110, and the film collecting part 134 may be positioned on the other side of the second mold die 110. The film supply part 132 may supply the multi-layered film 136 to the film collecting part 134 via the cavity 111 of the second mold die 110, and the film collecting part 134 may collect the entire or a portion of the multi-layered film 136 as described above.

The multi-layered film 136 may include a release film 137 contacting the cavity 111 of the second mold die 110, and a marking film 138, contacting the molding resin 112. The release film 137 may separate the molding resin 112 from the second mold die 110 when withdrawing the molded partially completed package 30 from the cavity 111 as will be further described below. The marking film 138 may adhere to the molding resin 112 during curing, by pressurizing and heating the molding resin 112 and the marking film 138. The marking film 138 may be formed of a material having a thermosetting point lower than that of the release film 137 so that when the molding resin 112 is cured through heat and/or pressure in the first and second mold dies, the marking film 138 may be pressed and adhered and/or fixed to the molding resin 112. In addition, after curing, the release film 137 may allow the molding resin 112 and the second mold die 110 to be easily separated from each other. Furthermore, the marking film 138 may be a color tape, which may allow the mark to be more easily identified.

Example embodiments of the semiconductor molding apparatus 100′ are shown in FIGS. 6 and 7. The semiconductor package molding apparatus 100′ may include similar elements as described with reference to FIGS. 4 and 5, for example, a first mold die 120, a second mold die 110 and a multi-layered film supply unit 130. However, the semiconductor package molding apparatus 100′ differs from the semiconductor package molding apparatus 100 of the aforementioned example embodiments in that a different multi-layered film 136′ may be supplied to the cavity 111 of the second mold die 110. The multi-layered film 136′ may include a release film 137, a marking film 138, and a foaming film 139.

The foaming film 139 may be interposed between the release film 137 and the marking film 138. The foaming film 139 may produce gas during curing of the molding resin 112 such that the release film 137 and the marking film 138 may be easily separated from each other following curing. Similar to the previous example embodiments, the marking film 138 may adhere to the molding resin 112 during the molding process and the release film 137 may contact the cavity 111 so that the marking film 138 and the release film 137 may be easily separated from each other at least due to the foaming film 139 foaming.

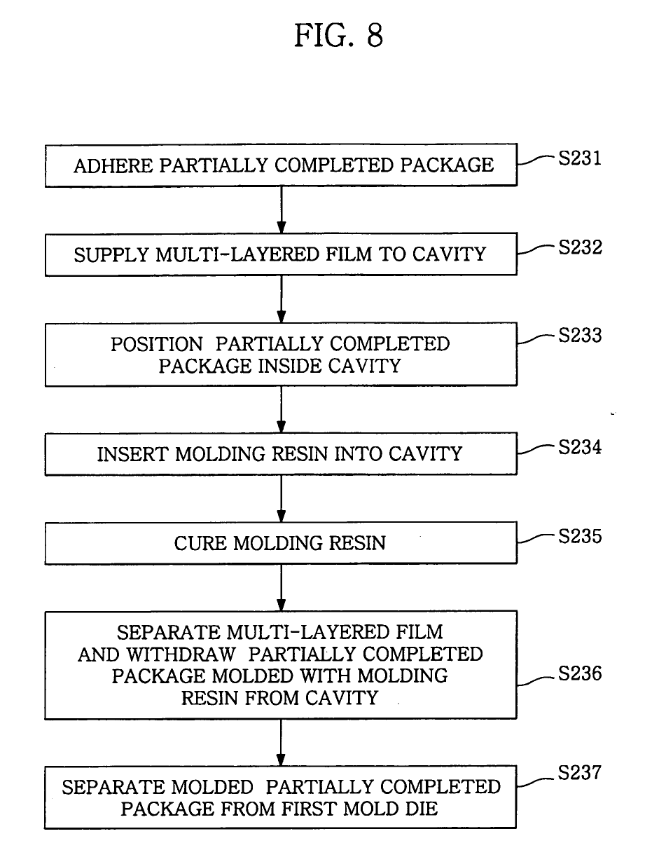

FIG. 8 shows other example embodiments of a semiconductor package molding method. The semiconductor package molding method may include adhering a semiconductor chip 34 to a substrate 31 and electrically connecting the semiconductor chip 34 and the substrate 31 to thereby form a partially completed package 40, which may then be adhered to a first mold die 120 (S231). The molding method may also include using a multi-layered supply unit 130 to supply a multi-layered film 136 to a cavity 111 of a second mold die 110 (S232). The method may further include positioning and/or moving the first or second mold die 120, 110 such that the partially completed package 40 may be positioned inside the cavity 111 of the second mold die 110 (S233) and inserting a molding resin 112 into the cavity 111 (S234). The method also may include curing the molding resin 112 (S235) using the first and second mold dies 120 and 110, withdrawing the molded partially completed package 30 from the cavity 111 while separating the multi-layered film 136 supplied to the cavity 111 (S236), and separating the molded partially completed package 30 from the first mold die 120 (S237).

In other example embodiments, the multi-layered film 136 may include a release film 137 contacting the cavity 111 of the second mold die 110, which may separate the molding resin 112 from the second mold die 110 when withdrawing the molded partially completed package 30 from the cavity 111, and a marking film 138, which may contact the molding resin 112 so as to be pressed and adhered to the molding resin 112 during curing of the molding resin 112. Using this multi-layered film 136 may allow easy separation of the molded partially completed package 30 from the first mold die 120, the molded partially completed package 30 having the marking film adhered thereto. The release film 137 may be separated from the marking film 138, which may allow the molded partially completed package 30 to be easily withdrawn from the cavity 111.

The marking film 138 may be formed of a material having a thermosetting point lower than that of the release film 137 such that the marking film 138 may be easily separated from the release film 137. The marking film 138 may be a color tape such that a mark may be more easily identified.

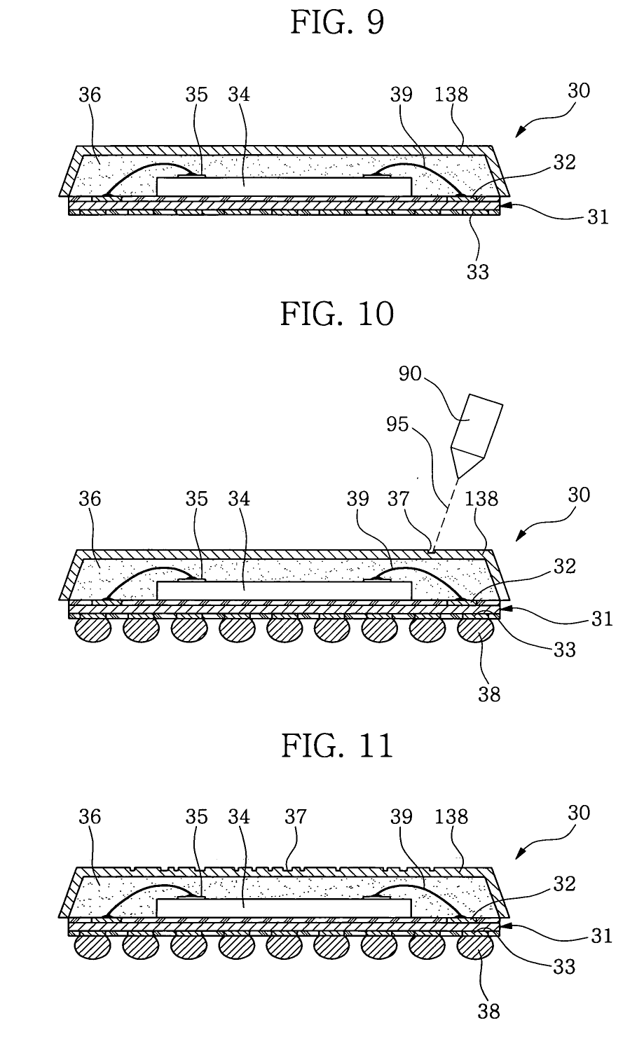

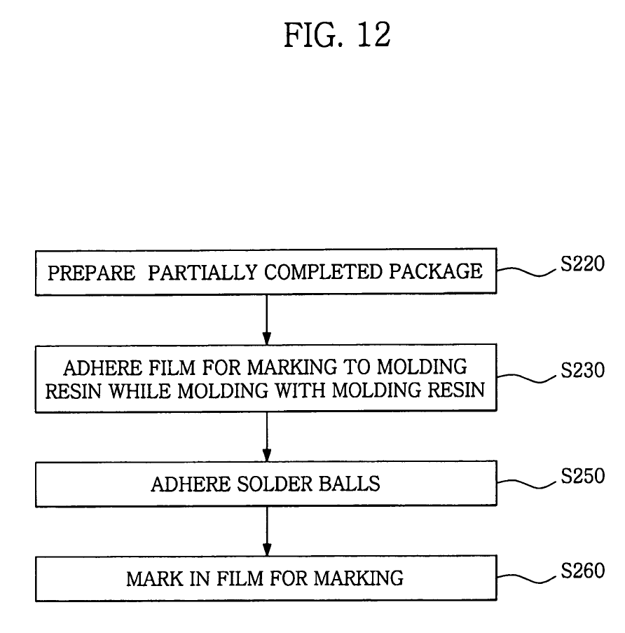

The multi-layered film 136 may be replaced with multi-layered film 136′, which may further include a foaming film 139 interposed between the release film 137 and the marking film 138 such that the release film 137 and the marking film 138 may be easily separated from each other. During curing the foaming film 139 may produce gas such that the release film 137 and the marking film 138 may be easily separated from each other. FIG. 9 is a cross-sectional view of a partially completed package molded by a semiconductor package molding apparatus according to example embodiments, and FIG. 10 is a cross-sectional view illustrating the state that solder balls are adhered to the partially completed package of FIG. 9 and then marked using a laser. FIG. 11 is cross-sectional of a semiconductor package according to example embodiments, and FIG. 12 is a flowchart illustrating a fabrication method of a semiconductor package according to example embodiments.

Other example embodiments, including a semiconductor package 30 and a fabrication method thereof will be described with reference to FIGS. 9 through 12. The semiconductor package 30 shown in FIG. 9 may include a substrate 31 including a connection terminal 32 for wire bonding formed on the top surface thereof and solder ball lands 33 for adhesion of solder balls 38 formed beneath the bottom surface thereof. The semiconductor package 30 may also include a semiconductor chip 34 adhered to the top surface of the substrate 31, wires 39 for electrically connecting connection terminal 32, which may be input/output terminals for the substrate 31, to pads 35 that may be input/output terminals for the semiconductor chip 34. Solder balls 38 may be adhered to the respective solder ball lands 33 and a molding resin 36 for encapsulating the semiconductor chip 34, the wires 39 and an electrical connection portion of the substrate 31 may also be included (FIG. 10). A marking film 138 may be adhered to an outer surface of the molding resin 36, and may have a mark 37, e.g., a lot number or management number, marked in the marking film 138 (FIG. 11).

The substrate 31 may be a lead frame or PCB and the semiconductor chip 34 may adhere to the substrate 31 by an adhesive, e.g., epoxy. The wires 39, which may electrically connect the substrate 31 to the semiconductor chip 34, may be formed of a material having relatively electric conductivity, e.g., gold and/or silver. The molding resin 36 may include an epoxy molding resin, which may encapsulate the semiconductor chip 34, wires 39, and an electrical connection portion of the substrate 31. The marking film 138 may be a color tape. The color tape may allow improved visibility of mark 37 and may have a different color than the color of the molding resin 36, for example, the color of the molding resin 36 may be a black-based color and the marking film may be a red-based or yellow-based color tape.

Semiconductor package 30 according to example embodiments may not be limited to only a structure in which the substrate 31 and the semiconductor chip 34 are electrically connected to each other through wires 39, but may be applied to a structure by “flip chip bonding”, in which the substrate 31 and the semiconductor chip 34 are electrically connected to each other directly using a bonding pad. In such a structure, the molding resin 36 may encapsulate the semiconductor chip 34 and the electrical connection portion of the substrate 31.

As illustrated in FIGS. 9 through 12, example embodiments of a fabrication method of a semiconductor package may include preparing a partially completed package 40 including a substrate 31 and a semiconductor chip 34 electrically connected to each other (S220) and molding the partially completed package 40 with a molding resin 112 (S230). The method may also include adhering a marking film 138 to the molding resin 112 during the molding process (S250) and marking a mark 37 in the marking film 138 (S260). The molding process may begin with a partially completed package 40 that is not molded with the molding resin 112 and when completed may produce a finished semiconductor package 30. Marking the mark 37 in the marking film 138 (S260) may include irradiating a laser beam 95 onto the marking film 138 using a laser irradiator (90 of FIG. 10).

The molding method illustrated in FIG. 8, may be employed to mold the partially completed package 40 with the molding resin 112 (S230) and adhering the marking film 138 to the molding resin 112 (S250), illustrated in FIG. 12. For example, a semiconductor chip 34 may adhere to a substrate 31 and electrically connect the semiconductor chip 34 and the substrate 31 to thereby form a partially completed package 40, which may then be adhered to a first mold die 120 (S231). A multi-layered supply unit 130 may be used to supply a multi-layered film 136 to a cavity 111 of a second mold die 110 (S232). The first or second mold die 120, 110 may be positioned or moved such that the partially completed package 40 may be positioned inside the cavity 111 of the second mold die 110 (S233). A molding resin 112 may be inserted into the cavity 111 (S234) and cured using the first and second mold dies 120 and 110 (S235). The molded partially completed package 30 may be withdrawn from the cavity 111 while separating the multi-layered film 136 supplied to the cavity 111 (S236). The molded partially completed package 30 may be separated from the first mold die 120 (S237).

The multi-layered film 136 in the above method may include a release film 137 contacting the cavity 111 of the second mold die 110, which may separate the molding resin 112 from the second mold die 110 when withdrawing the molded partially completed package 30 from the cavity 111, and a marking film 138, which may contact the molding resin 112 so as to be pressed and adhered to the molding resin 112 during curing of the molding resin 112. Using this multi-layered film 136 may allow easier separation of the molded partially completed package 30 from the first mold die 120, the molded partially completed package 30 having the marking film adhered thereto. The release film 137 may be separated from the marking film 138, which may allow the molded partially completed package 30 to be more easily withdrawn from the cavity 111.

The marking film 138 may be formed of a material having a thermosetting point lower than that of the release film 137 such that the marking film 138 may be easily separated from the release film 137. The marking film 138 may be a color tape such that a mark may be more easily identified.

The multi-layered film 136 may be replaced with multi-layered film 136′, which may further include a foaming film 139 interposed between the release film 137 and the marking film 138 such that the release film 137 and the marking film 138 may be more easily separated from each other. During curing, the foaming film 139 may produce gas such that the release film 137 and the marking film 138 may be more easily separated from each other.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

For example, although it has been described in example embodiments that a semiconductor package is a ball grid array (BGA) package, example embodiments are not limited to only the BGA package but may be applied to various packages including a dual inline package (DIP).

What is claimed is:

1. An apparatus for molding a semiconductor package, comprising:
a first mold die for adhering a partially completed package thereto;
a second mold die having a cavity such that the partially completed package is positioned inside the cavity and a molding resin for encapsulating the partially completed package is inserted into the cavity; and
a multi-layered film supply unit for supplying a multi-layered film to the cavity of the second mold die.

2. The apparatus according to claim 1, wherein the multi-layered film includes a release film and a marking film.

3. The apparatus according to claim 2, wherein the marking film has a thermosetting point lower than that of the release film.

4. The apparatus according to claim 2, wherein the marking film includes a color tape.

5. The apparatus according to claim 2, wherein the multi-layered film further includes a foaming film between the release film and the marking film.

6. A semiconductor package, comprising:
a substrate;
a semiconductor chip electrically connected to the substrate;
a molding resin encapsulating the semiconductor chip and a portion of the substrate; and
a marking film on an outer surface of the molding resin having a mark.

7. The semiconductor package according to claim 6, wherein the marking film includes a color tape.

8. The semiconductor package according to claim 6, wherein the marking film is adhered to the outer surface of the molding resin by heat.

9. The semiconductor package according to claim 6, wherein the marking film is adhered to the outer surface of the molding resin by pressure.

10. The semiconductor package according to claim 6 further comprising:
a wire for electrically connecting an input/output terminal of the substrate to an input/output terminal of the semiconductor chip.

11. The semiconductor package according to claim 10 wherein the molding resin encapsulates the semiconductor chip, the wire, and an electrical connection portion of the substrate.

12. A method for fabricating a semiconductor package, comprising:
molding a partially completed package including a substrate and a semiconductor chip electrically connected to the substrate with a molding resin;
adhering a marking film to the molding resin during molding of the partially completed package; and
marking the marking film with a mark.

13. The method according to claim 12, wherein the adhering of the marking film to the molding resin further includes:
pressing and adhering the marking film to the molding resin using heat when molding the partially completed package.

14. The method according to claim 12, wherein the marking film includes a color tape.

15. The method according to claim 12, wherein the mark in the marking film is formed by irradiating a laser beam onto the marking film.

16. The method according to claim 12, wherein molding the partially completed package with a molding resin further includes:
adhering the partially completed package to a first mold die;
positioning the partially completed package inside a cavity of a second mold die;
inserting a molding resin into the cavity;
curing the molding resin using the first and second mold dies; and
withdrawing the molded partially completed package from the cavity.

17. The method according to claim 16, wherein the curing includes heat and pressure.

18. The method according to claim 16, further including:
using a multi-layered film supply unit to provide a multi-layered film comprising a release film and a marking film, to the cavity of the second mold die before inserting the molding resin into the cavity; and
separating the release film and the marking film when withdrawing the molded partially completed package from the cavity.

19. The method according to claim 18, wherein during the curing, the release film contacts the cavity of the second mold die and the marking film contacts the molding resin.

20. The method according to claim 18, wherein the marking film has a thermosetting point lower than that of the release film.

21. The method according to claim 18, wherein the marking film includes a color tape.

22. The method according to claim 18, wherein the multi-layered film further includes a foaming film between the release film and the marking film, wherein the foaming film produces gas during curing of the molding resin such that the release and marking films separate from each other.

23. A method for molding a semiconductor package, comprising:
adhering a partially completed package to a first mold die;
using the multi-layered film supply unit to supply to a cavity of a second mold die a multi-layered film comprising a release film and a marking film;
positioning the partially completed package inside the cavity of the second mold die; and
inserting a molding resin into the cavity.

24. The method according to claim 23, further including:
curing the molding resin;
separating the multi-layered film; and
withdrawing the molded partially completed package from the cavity.

25. The method according to claim 24, wherein during the curing, the release film contacts the cavity of the second mold die and the marking film contacts the molding resin.

26. The method according to claim 23, wherein the marking film is formed of a material having a thermosetting point lower than that of the release film.

27. The method according to claim 23, wherein the marking film includes a color tape.

28. The method according to claim 23, wherein the multi-layered film further comprises a foaming film between the release film and the marking film, wherein the foaming film produces gas during curing of the molding resin such that the release and marking films separate from each other.
